(19) United States
(12) Patent Application Publication
(10) Pub. No.: US 2021/0202339 A1
(43) Pub. Date: Jul. 1, 2021

(54) RELIABLE SEMICONDUCTOR PACKAGES

(71) Applicant: UTAC Headquarters Pte. Ltd., Singapore (SG)

(72) Inventors: Surachai Uraisakul, Bangkok (TH); Siriwanna Ounkaew, Bangkok (TH); Panumard Thammavet, Bangkok (TH); Tanawan Chaowasakoo, Bangkok (TH)

(21) Appl. No.: 17/138,741

(22) Filed: Dec. 30, 2020

Related U.S. Application Data
(60) Provisional application No. 62/955,417, filed on Dec. 31, 2019.

(51) Int. Cl. H01L 23/31; H01L 23/495; H01L 23/00; H01L 21/48; H01L 21/56

(52) U.S. Cl. CPC H01L 23/3142; H01L 23/49558; H01L 24/45; H01L 23/49513; H01L 24/37; H01L 25/0657; H01L 21/4825; H01L 21/565; H01L 24/84; H01L 2224/3769; H01L 23/49586

(57) ABSTRACT

The present disclosure is directed to improving package adhesion to provide more reliable semiconductor packages. The semiconductor package may be, for example, a leadframe including one or multiple dies attached thereto. The semiconductor package may include only clip bonds or only wire bonds or a combination of clip bonds and wire bonds. An adhesion enhancement coating may be disposed in between the package substrate and the encapsulant to improve package adhesion. For example, the adhesion enhancement coating enhances the sealing by bonding respectively with the inorganic materials of the package substrate and the organic materials of the encapsulant.

### CROSS-REFERENCE TO RELATED APPLICATION

This application claims the benefit of U.S. Provisional Application Ser. No. 62/955,417, filed on Dec. 31, 2019, which is herein incorporated by reference in its entirety for all purposes.

### FIELD OF THE INVENTION

The present invention generally relates to semiconductor packages and the manufacturing method of such packages. More specifically, the present invention is directed to improving package adhesion to provide more reliable semiconductor packages.

### BACKGROUND

The recent rapid dissemination of smartphones and other mobile and wearable electronic terminals reflect the demand for faster, thinner and smaller products which are more compact and power-efficient. To meet these requirements, packaging employing leadframes is widely utilized for its advantages such as a lower cost and a smaller footprint package. Moreover, clip bonds are increasingly being used together with wire bonds or in lieu of wire bonds in leadframe packages to provide lower resistance and inductance, improving speed and thermal performance.

Typically, an encapsulant is used to seal the semiconductor package after all the components are assembled on the leadframe. However, such package suffers from delamination issue, which negatively impacts package reliability. For example, delamination between the chip components, the leadframe and the encapsulant. This is due to poor adhesion between the encapsulant mold and the copper components present on the chip or the leadframe.

Therefore, from the foregoing discussion, there is a desire to provide improved adhesion within the package and reduced effect of delamination, which in turn improves reliability of semiconductor packages.

### SUMMARY

In one embodiment, a device including a package substrate having top and bottom major package substrate surfaces, the top major package surface includes a die attach region. The device also includes a die disposed on the die attach region and the die includes first and second major die surfaces. The second major die surface is attached to the die attach region. The device further includes an adhesion enhancement layer disposed on a metallic component of the device, and an encapsulant. The encapsulant covers exposed portions of the package substrate and the die. The adhesion enhancement layer enhances adhesion of the encapsulant to the metallic component of the device.

In another embodiment, a method for forming a device includes providing a package substrate having top and bottom major package substrate surfaces and the top major package surface includes a die attach region. The method further includes attaching a second major die surface of a die onto the die attach region and a first major die surface of the die includes a die pad. The method includes depositing an encapsulant on the package substrate to cover exposed portions of the package substrate and the die. The encapsulant bonds with an adhesion enhancement layer disposed on a metallic component of the device which enhances adhesion of the encapsulant to the metallic component of the device.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIGS. 1a to 1c show various exemplary embodiments of a semiconductor package;

FIG. 2a shows an exemplary process of a chemical reaction to form a polysiloxane layer in an organic-inorganic interface;

FIG. 2b shows applications of the polysiloxane layer in different types of organic-inorganic interfaces;

FIG. 3 shows an exemplary process to form a polysiloxane layer using organosilanes;

FIGS. 4a to 4b show various exemplary process flows of forming an embodiment of a semiconductor package;

FIGS. 5a to 5b show another exemplary process flow of forming an embodiment of a semiconductor package; and

FIG. 6 shows another exemplary process flow of forming an embodiment of a semiconductor package.

### DETAILED DESCRIPTION

Embodiments relate to semiconductor packages and the manufacturing method of such packages. More specifically, the present invention is directed to improving package adhesion to provide more reliable semiconductor packages. A semiconductor package may include a single or multiple semiconductor dies or chips. The semiconductor package may include only clip bonds or only wire bonds or a combination of clip bonds and wire bonds. In addition, in the case of a multiple die package, the dies may be configured in a planar or stacked configuration or a combination thereof.

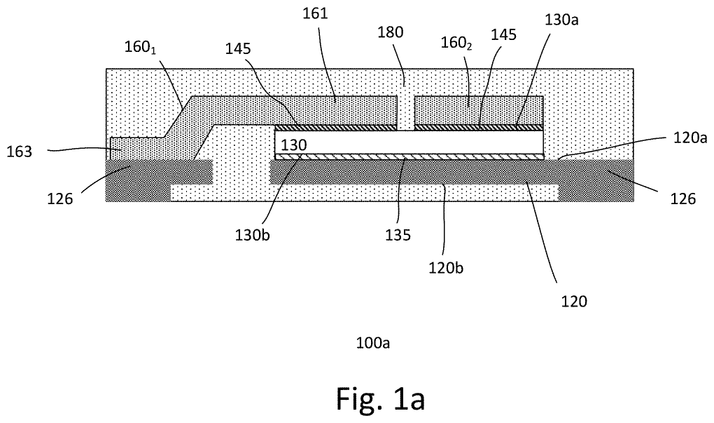

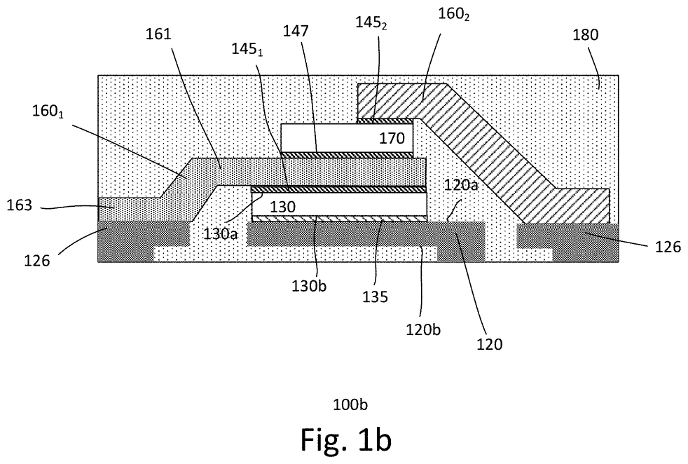

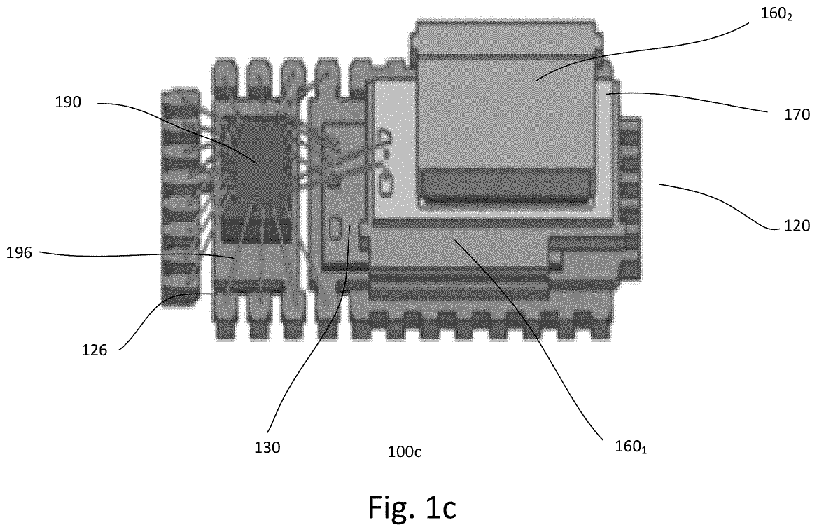

FIGS. 1a to 1c show various exemplary embodiments of a semiconductor package. The various embodiments include common elements. Common elements may not be described or described in detail.

Referring to FIG. 1a, the semiconductor package 100a, for example, is a package for a power IC. Providing a semiconductor package for other types of ICs may also be useful. As shown, the semiconductor package includes a package substrate 120 having opposing first and second major surfaces 120a and 120b. The first major surface 120a may be referred to as the top or active package surface and the second major surface 120b may be referred to as the bottom package surface. Other designations for the surfaces may also be useful.

The package substrate, in one embodiment, is a leadframe, such as a copper or copper alloy leadframe. Other types of leadframes or package substrates may also be useful. For example, the leadframe may be in a leadframe strip with a row or matrix of leadframes. This enables processing of multiple packages in parallel before they are subsequently singulated into individual packages. Other types of package substrates may also be useful.

The top package surface of the package substrate includes a die attach region for accommodating one or more dies. Providing multiple die attach regions for multiple dies may also be useful. For example, two die attach regions may be provided for attaching two dies. Terminal pads 126 may be provided on the top package surface. The terminal pads may surround or be located on one or more sides of the die attach region. The number and placement of terminal pads may depend on the number of die terminals or pads on the die and package configuration.

As shown, a die 130 is attached to the die attach region of the package substrate. For example, a bottom surface 130b of the die is attached to the die attach region of the package substrate by a die adhesive 135. In other embodiments, the package may include multiple dies. The multiple dies may be arranged in a stack configuration (vertical), a planar configuration (horizontal), or a combination of stack and planar. Other die configurations may also be useful.

The die may be a power MOSFET IC. The power MOSFET IC, for example, includes a drain, source and gate connections or die terminals. For example, the die includes 3 die pads or die terminals to provide external connections to the die. In one embodiment, the drain die pad is disposed on the bottom die surface 130b of the die while the source and gate die pads are disposed on top die surface 130a of the die. For example, the die attach region of the package substrate is coupled to the drain die pad. The die attach region is coupled to a drain terminal pad. In such a case, the die adhesive is a conductive material with high thermal conduction. The conductive material, for example, may include a solder paste or a sintering material. Other types of dies with other numbers of die pads may also be useful. In addition, the die may be configured with only die pads on the top die surface. In the case that the die does not have die pads on the bottom die surface, the die adhesive may be a non-conductive die adhesive.

Clip bonds are provided to electrically couple die pads on the top die surface 130a to terminal pads 126 of the package substrate. As shown, the package includes first and second clip bonds 160₁₋₂ for electrically coupling the die pads to the terminal pads. For example, the first and second clip bonds may be coupled to the source and gate die pads on the top die surface. A clip-die (clip to die) conductive bonding layer 145 bonds the upper portion 161 of the clip bond to a die pad on the top die surface whereas a clip-substrate (clip to substrate) conductive bonding layer (not shown) bonds the lower portion 163 of the clip bond to a terminal pad of the package substrate. In one embodiment, the conductive bonding layers are the same or similar to the conductive die adhesive 135. For example, the bonding layers may include a conductive material with high thermal conduction, such as a solder paste or a sintering material.

The clip bonds may be configured to have a stepped profile. Alternatively, other clip bond profiles or configurations which can electrically connect a die pad to a terminal pad may also be useful. In one embodiment, a clip bond is formed as a metallic clip bond, such as a copper or copper alloy clip bond. For example, the clip bond is formed of a conductive sheet, such as a copper or copper alloy sheet. Other types of metal sheets may also be used to form the clip bond. The conductive sheet may be singulated to form individual clip bonds and shaped to have a desired profile, such as the stepped profile. Other profiles for the conductive sheet may also be useful. Forming the clip bonds by other techniques may also be useful. For example, the clip bond may be formed by molding, stamping or from multiple parts bonded together to have the desired shape.

Illustratively, the die is coupled to the package substrate with two clip bonds. It is understood that the number of clip bonds may, for example, depend on the number of die pads on the top die surface. For example, one clip bond may be provided for each top die pad and terminal pad pair, each bonded by a clip-die conductive bonding layer and a clip-substrate conductive bonding layer. The dimensions of the clip bonds, as well as die pads, may differ based on power requirements. The conductive bonding layers should be contained within their respective contact regions to avoid shorting with other contact regions due to overflow. For example, the clip-die conductive bonding layers should be contained within the respective clip bonds.

In some cases, the die may include a combination of clip bonds and wire bonds for connecting the die pads on the top die surface to terminal pads on the lead frame. For example, both clip bonds and wire bonds may be provided to connect the die pads to respective terminal pads. Other configurations of connecting the die to the package substrate may also be useful. For example, in another embodiment, only wire bonds are utilized to connect the die pads to respective terminal pads.

An encapsulant 180 is disposed on the package substrate. As shown, the encapsulant 180 covers the package substrate, the die, and the clip bond, including the lower portions 163 of the clip bonds. This results in a leadless package. For example, the terminal pads are disposed on the backside of the package within the encapsulant. Alternatively, the encapsulant exposes the leads of the package substrate. For example, the leads formed from the clip bonds and the package substrate are exposed. This results in a package with leads. The encapsulant, for example, may be a mold compound. Other types of encapsulants may also be useful.

FIG. 1b shows a semiconductor package 100b. The package is similar to that described in FIG. 1a. Common elements may not be described or described in detail. However, unlike FIG. 1a, the package is a multi-die stacked package with a second die 170 stacked on the first die 130. Providing other numbers of stacked dies may also be useful.

As shown, a second die 170 is stacked on top of a first die 130. For example, the package includes a multiple die stack configuration, with clip bonds for coupling to the first die and to the second die. Although a two-die stack is illustrated, providing a die stack having other numbers of dies may also be useful. The first die is attached to the die attach region of the package substrate using a die adhesive 135. A first clip bond 160₁ connects a die pad on the top die surface to a terminal pad 126 on the package substrate 120. For example, a clip-die conductive bonding layer 145₁ bonds the die pad to the first clip bond and a clip-substrate conductive bonding layer bonds the clip bond to the terminal pad. Depending on the number of die pads on the first die, more than one first clip bonds may be employed.

The second die 170 is attached to a top surface of the upper portion 161 of the first clip bond 160₁ by a die-clip (die to clip) conductive bonding layer 147. The first clip bond, for example, provides a common signal to both the first and second dies. For example, the second die has a die pad on its bottom die surface which is coupled to the first clip bond.

A second clip bond 160₂ is provided to electrically connect the second die to the package substrate. The second clip bond may have any profile, as previously described. A second clip-die conductive bonding layer 145₂ bonds the second clip bond to a die pad on a top surface of the second die and a second clip-substrate bonding layer bonds the lower portion of the second clip bond to another terminal pad 126 of the package substrate. The lower portions 163 of the first and second clip bonds are bonded to respective terminal pads 126. In addition, the second clip bond may include multiple second clip bonds, depending on the number of die pads on the top surface of the second die to be connected.

Although the package is shown with clip bonds for coupling the dies to the package substrate, it is understood that a combination of wire bonds and clip bonds may be used to electrically connect the dies to the package substrate. Other configurations of connecting the dies to the package substrate may also be useful.

FIG. 1c shows a semiconductor package 100c which is similar to that described in FIGS. 1a to 1b. Common elements may not be described or described in detail. However, unlike FIGS. 1a to 1b, the package is a multi-die package in which first and second dies 130 and 170 are stacked and a third die 190 is disposed on the package substrate 120 in a planar configuration with the first die. A first clip bond 160₁ is disposed over the first die and electrically connects the first die to the package substrate. The second die is disposed on the first clip bond. A second clip bond 160₂ is disposed over the second die and electrically connects the second die to the package substrate. As for the third die, it is connected by wire bonds 196 to the package substrate. In addition, wire bonds connect the second die to the first die. An encapsulant (not shown) encapsulates the dies of the package. Other die configurations of the package may also be useful.

In one embodiment, a metallic component of the various packages may be coated with an adhesion enhancement coating. The adhesion enhancement coating is configured to enhance adhesion between the encapsulant 180 and the metallic component. The metallic component, for example, may be the package substrate, in the case of a leadframe package substrate, or a clip bond. In some embodiments, one, some, or all the metallic components are coated with the adhesion enhancement coating. For example, the leadframe may be coated, a clip bond may be coated, some clip bonds may be coated, all clip bonds may be coated or a combination of the metallic components are coated, including one, some or all of the metallic components.

The adhesion enhancement coating may be applied to a metallic component prior to assembly. For example, the adhesion enhancement coating may be applied to one, some or all metallic components prior to assembly. In other cases, the adhesion enhancement coating may be applied to the package after assembly but prior to encapsulation by the encapsulant. In such cases, the exposed portions of all metallic components are coated. In yet other cases, the adhesion enhancement coating may be applied to a metallic component before assembly and after assembly. For example, one, some or all metallic components may be applied with the adhesion enhancement coating before assembly and the package may be applied with the adhesion enhancement coating after assembly.

In one embodiment, the adhesion enhancement coating includes a polysiloxane layer. The chemical structure of the polysiloxane layer includes 2 types of functional groups which bond respectively with the inorganic materials of the package substrate and the organic materials of the encapsulant. This enhances the sealing strength between the metallic component or components of the package and the encapsulant (package-encapsulant interface) and prevents delamination. In one embodiment, the polysiloxane layer is a monolayer. Providing multiple layers crosslinked to form a polysiloxane network may also be useful.

The polysiloxane layer may be formed using silane compounds. The type of silane compounds employed may depend on the chemical compatibility of the functional groups of the silane compounds with the organic and inorganic substrates of the package-encapsulant interface. In one embodiment, the silane compounds employed are organosilanes. An organosilane has a chemical formula consisting of:

Y₃SiR′₁X,

where
Y is a hydrolyzable functional group including, for example, an alkoxy (—OR), an aryloxy, an amine, or a halogen,
R′ is a linker including, for example, an alkylene linker, and
X is an organofunctional group including, for example, an amino, a mercapto, an ureido, or a chloro.

As shown in the chemical formula above, similar to any silane compounds, the organosilane has 2 functional groups configured to exhibit a bifunctionality. For example, the hydrolyzable functional group Y bonds with an inorganic substrate, in this case, the metallic component(s) of the package, whereas the organofunctional group X bonds to an organic polymer, such as the encapsulant. The resulting polysiloxane layer serves as a bridge between the metallic component(s), such as copper component, of the package and the encapsulant. Other silane compounds such as Organotitanate, Zirconate, Zircoaluminate or Alkyl phosphate ester may also be used to form adhesion enhancement coating. Providing other types of adhesion enhancement coating may also be possible. For example, the adhesion enhancement coating may include organic coupling compounds such as imidazole or organic amine coupling compounds such as AEPAS.

Organosilanes may be applied on the package by a solution deposition technique. For example, organosilanes may be prepared in a suitable solvent and applied on the package by a spray-on technique. Alternatively, it may also be possible to employ the organosilanes-containing solution as a dip bath. The deposited organosilanes react with the metallic component of the package to form a polysiloxane layer bonded to the metallic component. Other techniques for coating the package may also be possible. For example, techniques including chemical vapor deposition (CVD) or physical vapor deposition (PVD) techniques. For CVD and PVD techniques, they are used to coat the metallic component prior to assembly. As for spray-on or other coating techniques, they can be used for coating prior or after package assembly.

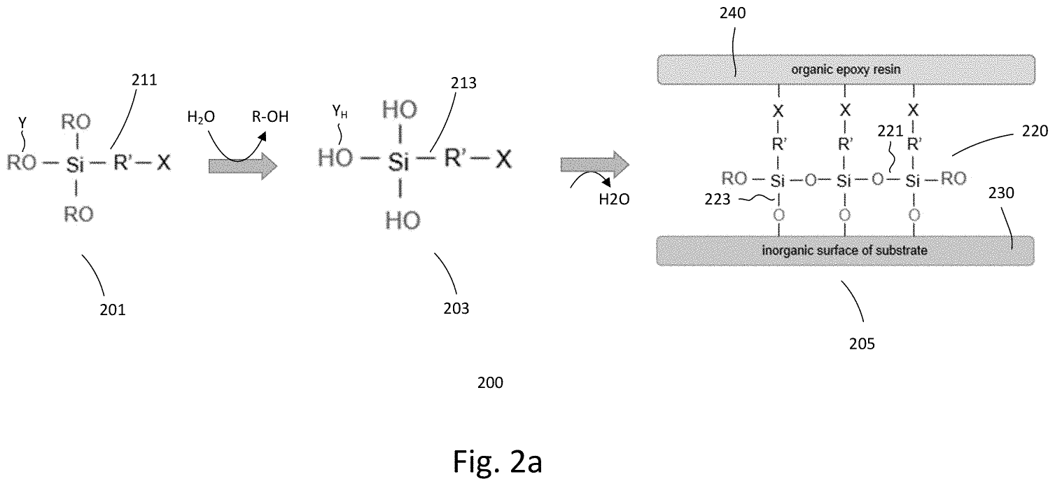

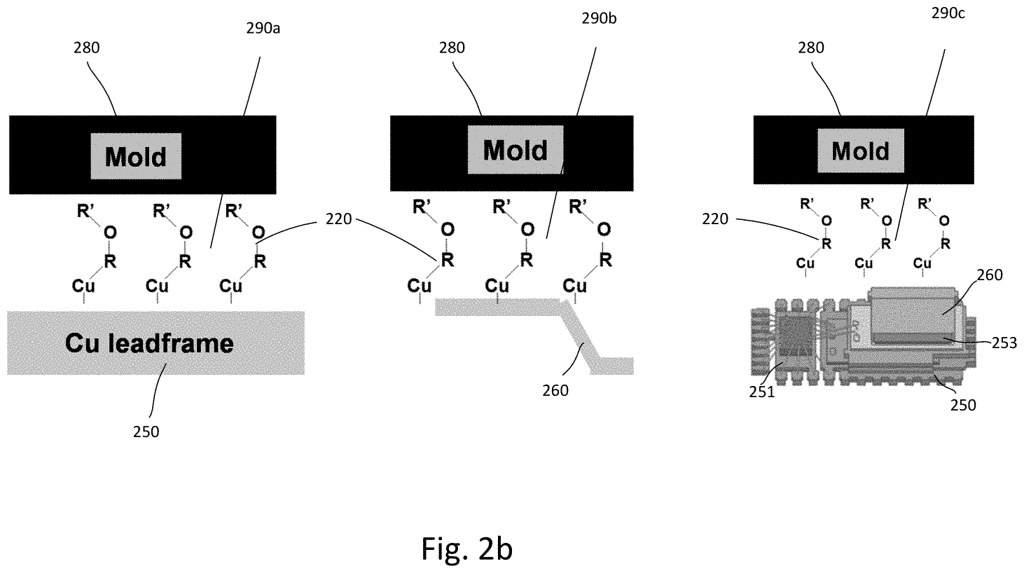

FIG. 2a shows an exemplary process 200 of a chemical reaction to form a polysiloxane layer in an organic-inorganic interface while FIG. 2b shows applications of the polysiloxane layer in different types of organic-inorganic interfaces.

Referring to FIG. 2a, in 201, organosilane 211 is provided as the starting material or first reactant of the reaction. For example, organosilanes are converted to active intermediates by a hydrolysis reaction in 203, and the active intermediates subsequently react to form the polysiloxane layer 220 which binds the inorganic and organic substrates together in 205. Although only one organosilane molecule is shown, it is understood that more than one organosilane molecules may be present in the reaction.

As shown in 201, the hydrolyzable functional group Y of the organosilane 211 may be an alkoxy (—OR) group such as methoxy or ethoxy group. Other oxygen atom containing carbon groups such as aryloxy groups may also be possible. Alternatively, other types of functional groups including halogen (such as chloride), anime, acetamido, acetyl containing groups may also be utilized. The hydrolyzable functional group Y, when hydrolyzed, is configured to bond with other compounds containing hydroxyl groups. Preferably, the hydrolyzable group Y is compatible to bond with hydroxyl groups present on inorganic substrates such as the metallic component of the package substrate, clip bonds, or any other package components. As shown, the organosilane 211 includes 3 hydrolyzable functional groups Y. For example, the organosilane is a trialkoxysilane. The 3 hydrolyzable functional groups Y may be the same or different types. Providing silanes other than organosilanes may also be possible. For example, silane compounds with less than 3 hydrolyzable functional groups Y.

The organosilane 211 may include an organofunctional group X which is linked to a Si atom of the organosilane by a linker molecule R′. The organofunctional group X is a non-hydrolyzable group configured to bond to an organic substrate. Preferably, the organofunctional group X is selected based on its chemical compatibility with the organic substrate of the encapsulant. For example, in the case when epoxy is used for the encapsulant, X may be an amino-containing group. Providing other types of organofunctional groups such as mercapto, ureido, chloro containing groups may also be possible.

During hydrolysis in 203, organosilanes are hydrolyzed to form reactive intermediates. Preferably, hydrolysis of organosilane is conducted in the presence of water. Each hydrolyzable group Y of one organosilane molecule reacts with an equimolar of water molecule to form a hydrolyzed functional group Y_{H}. For example, Y_{H} may be a hydroxyl group. The organofunctional group X is not hydrolyzed. The reactive intermediates may include silanols 213 containing the hydrolyzed functional groups Y_{H} and the organofunctional group X. By-products may be formed during the hydrolysis. For example, the by-product includes alcohol molecules R—OH. As shown, in the case of an organosilane 211 with 3 hydrolyzable groups Y, a complete hydrolysis generates an active silanol 213 containing 3 hydrolyzed functional groups Y_{H} (hydroxyl groups) and the organofunctional group X. Alcohol R—OH is generated as a by-product during the reaction.

The hydroxyl groups of the silanol are configured to react and bond with other hydroxyl groups. For example, in the presence of a reaction mix with multiple silanol molecules, hydroxyl groups of one silanol molecule may bond with hydroxyl groups of other silanol molecules to form oligomers via a condensation reaction. For example, as shown in 205, condensation occurs between silanol molecules to form silanol-silanol bonds. In this case, the silanol-silanol bond is a chemical bond. For example, the silanol-silanol bond is a silanol-silanol covalent bond (Si—O—Si covalent bond) 221. Condensation may be a self-condensation. For example, self-condensation can happen as long as there are at least 2 silanols with free hydroxyl groups. Alternatively, condensation between silanol molecules can be sped up by performing a drying or curing process in 205.

In the presence of an inorganic substrate 230 with hydroxyl groups, such as a conductive material, the hydroxyl groups of the silanol may also bond with hydroxyl groups of the inorganic substrate. For example, a silanol-metal bond is formed on the inorganic substrate. The silanol-metal bond may be an intermolecular bond, such as a hydrogen bond (not shown). Forming a silanol-metal bond which is a chemical bond may also be possible. For example, as shown in 205, a silanol-metal covalent bond (Si—O-M covalent bond) 223 is formed on the inorganic substrate 230. The drying or curing process performed in 205 forms the Si—O-M covalent bonds. For example, curing processes such as UV curing or thermal curing may be employed.

As a result, a polysiloxane layer 220 is formed and bonded to the surface of the inorganic substrate 230. The organofunctional groups X on the polysiloxane layer remain free until an organic substrate 240 is disposed over the polysiloxane layer. For example, the organofunctional groups X form bonds with the organic substrate. This enables the polysiloxane layer to bind the organic and inorganic substrates tightly together.

In one embodiment, as shown in FIG. 2b, the polysiloxane layer 220 may be formed in an interface 290a between the package substrate 250 and the encapsulant 280. For example, the polysiloxane layer bonds to the metallic component of the package substrate as well as the encapsulant. Alternatively, it is formed in an interface 290b between the clip bonds 260 and the encapsulant 280. In such cases, the polysiloxane layer bonds to the metallic component of the clip bonds as well as the encapsulant. Other types of interfaces may also be possible. For example, interfaces 290c between exposed surfaces of the metallic components of the package, including the package substrate 250, dies 253, clip bonds 260 and wire bonds 251, and the encapsulant 280.

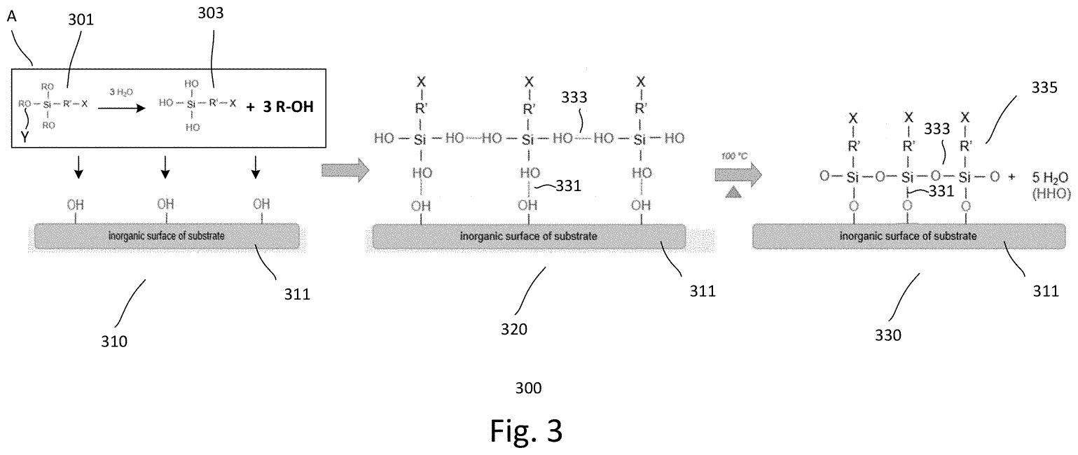

FIG. 3 shows an exemplary process 300 to form a polysiloxane layer using organosilanes.

In 310, organosilanes are prepared in a solution A. In one embodiment, solution A is an aqueous solution. For example, solution A includes water. As shown, an organosilane molecule 301 includes 3 hydrolyzable functional groups Y and an organofunctional group X. Preferably, the organosilane is soluble in water. For example, the organosilane is an aminosilane. Water initiates the hydrolysis reaction of organosilanes in solution A. For example, once water is added, organosilanes are hydrolyzed to form reactive intermediates 303 in the solution. The rate of hydrolysis depends on the concentration of water. For example, as shown, in the case of an organosilane molecule with 3 hydrolyzable functional groups Y, a molar ratio of 1:3 of organosilane to water may be employed to ensure complete hydrolysis of the organosilane molecule to form a silanol molecule with 3 hydroxyl groups. Providing a molar ratio of less than 1:3 molar ratio may also be possible. For example, when water is the limiting reactant in the hydrolysis reaction, the reactive intermediates generated may include a mixture of silanols with different numbers of hydroxyl groups, such as silanols with 1, 2 or 3 hydroxyl groups. Depending on the types of organosilanes used, the solution A may include additional additives such as catalysts.

As discussed, alcohol by-products R—OH may be generated during the hydrolysis. For example, the solution A may include alcohol by-products. The amount of alcohol generated may depend on the number of hydrolyzable functional groups on the organosilane as well as the rate of hydrolysis. For example, 1 organosilane molecule that is completely hydrolyzed generates 3 molecules of alcohol by-products. The alcohol by-products may be removed by evaporation during a subsequent curing step.

Solution A may include a working organosilane concentration. For example, the solution A is prepared by dissolving organosilane at 30% concentration in water. For example, one part (gram) of pure organosilane is mixed with 2.33 parts (grams) of water. In one embodiment, solution A is directly prepared from a stock organosilane. For example, the stock organosilane includes purely organosilane. For example, the stock organosilane includes an organosilane concentration of substantially 100%. A diluent, such as alcohol or any other solvent, is used to dilute the stock organosilane to the working concentration. As shown, solution A with the working organosilane concentration is deposited on the top surface of the inorganic substrate 311, for example, the package substrate.

In 320, due to the presence of hydroxyl groups on the top package surface, one of the hydroxy groups of each silanol molecule bonds by, for example, a hydrogen bond 321, to a respective hydroxyl group of the package substrate 311. Each silanol will only form one hydrogen bond with one hydroxyl group on the package substrate. The other hydroxyl groups on the silanol molecule are free to form hydrogen bonds 323 with hydroxyl groups of neighboring silanol molecules. For example, only intermolecular bonds between silanol molecules as well as intermolecular bonds between the package substrate and silanol molecules are formed. For example, at this stage, no chemical bonds are formed. Self-condensation to form Si—O—Si covalent bonds is negligible due to the presence of alcohol.

A drying or curing process is then performed at 330 to form chemical or covalent bonds. For example, the hydrogen bonds between the hydroxyl groups of the silanol molecules and the package substrate are converted to covalent bonds (Si—O-M covalent bonds) 331. For example, the hydrogen bonds between the hydroxyl groups of neighboring silanol molecules are converted to covalent bonds (Si—O—Si covalent bonds) 333. The water by-products generated by the formation of covalent bonds are removed by evaporation during the drying or curing process. At the same time, the alcohol by-products formed during the hydrolysis reaction are also removed by evaporation. As a result of the covalent bonds, a polysiloxane layer 335 is formed and bonded to the top package surface of the package substrate 311. The organofunctional groups X present on the polysiloxane layer 335 remain free to bond to the organic substrate when the organic substrate is disposed over the polysiloxane layer.

As already discussed, the organosilanes-containing solutions may be applied on surfaces of the package substrate, clip bonds, or other metallic components of the package by a spray-on technique or employed as a dip bath. Alternatively, other techniques such as CVD or PVD may be performed.

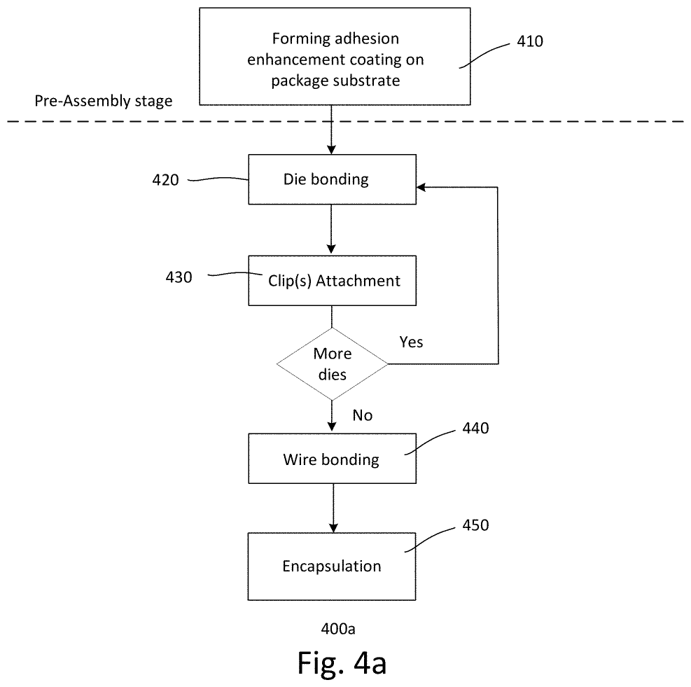

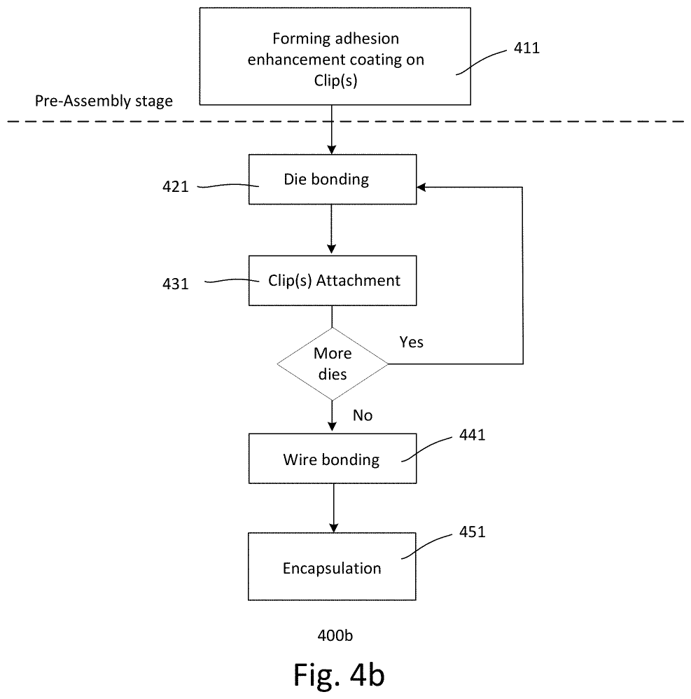

FIGS. 4a to 4b show various exemplary process flows of forming an embodiment of a semiconductor package. The package, for example, is similar to those described in FIGS. 1a to 1b and FIG. 2b. Common elements may not be described or described in detail.

Referring to FIG. 4a, a process flow 400a, for example, commences at 410. The process flow, as shown, is at a pre-assembly stage where dies are formed on a wafer and diced to form individual dies. Depending on the configuration of the semiconductor package, clip bonds, if needed, are formed using a conductive strip and singulated to form individual clip bonds.

The process includes providing a package substrate. The package substrate may include top and bottom package surfaces. In one embodiment, the package substrate is a leadframe, such as a copper or copper alloy lead frame. The top package surface of the package substrate may include a die attach region and terminal pads disposed outside of the die attach region. Providing other types of leadframes or package substrates may also be useful. In one embodiment, the process includes providing the package substrate as a leadframe strip with a row or matrix of leadframes.

An adhesion enhancement coating is applied on the package substrate. In one embodiment, the adhesion enhancement coating covers the top or bottom package surface. Alternatively, the top and bottom package surfaces, as well as sides of the package substrate may be coated with the adhesion enhancement coating. Other configurations of applying the adhesion enhancement coating may also be possible. The adhesion enhancement coating may include a polysiloxane layer formed by organosilane compounds. Utilizing other silane compounds to form the polysiloxane layer or forming other types of adhesion enhancement coating may also be useful.

In one embodiment, the adhesion enhancement coating is formed by a solution deposition technique. For example, organosilanes may be prepared in a suitable solvent and deposited on the package substrate by a spray-on technique. The suitable solvent may be an aqueous solution. After deposition, reactive intermediates of the organosilanes react with, for example, the metallic component of the package substrate to form a polysiloxane layer bonded to the package substrate. Other techniques for forming the adhesion enhancement coating may also be possible. For example, techniques such as CVD or PVD.

Assembly of the package may begin from 420. For example, as shown, a die is attached by a die adhesive to the die attach region of the package substrate in 420. For example, depending on the arrangement of the die pads on the die, the die adhesive may be a conductive or non-conductive material.

Clip bonds, in one embodiment, are attached to the die and the package substrate at 430. For example, the clip bonds electrically couple die pads on the top die surface to the terminal pads on the package substrate. A clip-die conductive bonding layer is applied on the top die surface to bond the upper portion of the clip bond thereto while a clip-substrate conductive bonding layer (clip to substrate bonding layer) bonds the lower portion of the clip bond to a terminal pad of the package substrate. If there are no more dies to attach, the process continues to 440.

If there are more dies for attaching, the process flow returns to repeat 420 and 430 until there are no more dies to attach. For example, in the case of a multiple stack die configuration, a second die is stacked on top of a first clip bond and second clip bonds are attached to couple the second die to the terminal pads of the package substrate. Alternatively, a second die may be attached side by side to a first die on 2 separate die attach regions. Once all the dies are attached and clip bonded, the process moves on to 440.

In one embodiment, wire bonds are formed at 440. The wire bonds connect the die pads on the top die surface to terminal pads on the top package surface of the package substrate.

In 450, an encapsulant, such as epoxy, is formed over the package substrate. The encapsulant covers the package substrate, exposed portions of the semiconductor components including the die, the clip bonds and the wire bonds. The epoxy may be formed by, for example, dispensing. Other techniques or materials may also be employed for the encapsulant. The encapsulant is cured thereafter. For example, the encapsulant is tightly sealed to the package substrate by the adhesion enhancement coating disposed in between.

Depending on the configuration of the semiconductor packages, the process flow 400a may not include forming clips bonds or wire bonds. For example, in the case when the semiconductor package does not include clip bonds, no clip bonds are provided in 430. As for cases when the semiconductor package does not include wire bonds, the process flow proceeds directly to form the encapsulation in 450 after there are no more dies to attach.

FIG. 4b shows a process flow 400b which is similar to the process flow 400a in FIG. 4a, except the package substrate is not coated with the adhesion enhancement coating during the pre-assembly stage in 411. For example, in 411, no adhesion enhancement coating is applied on the package substrate. Instead, the adhesion enhancement coating is formed on the conductive strip with clip bonds. For example, the adhesion enhancement coating covers top and bottom surfaces of the conductive sheet. For example, the adhesion enhancement coating covers exposed surfaces of the conductive sheet. Alternatively, the adhesion enhancement coating may only cover the top or bottom sheet surface. In one embodiment, organosilanes may be prepared in a suitable solvent and deposited on the conductive strip by spraying. Other techniques such as CVD or PVD techniques may also be useful for forming the adhesion enhancement coating. The conductive strip is then singulated to form individual clip bonds which are subsequently used during clip attachment in 431. As for the remaining process flow from 421 onwards, they are similar to the process steps 420 to 450 described in FIG. 4a, common elements may not be described or described in detail.

In one embodiment, depending on the configuration of the semiconductor package, the process flow 400b may not include forming wire bonds. In such cases, the process flow moves on directly to form the encapsulation in 451 when there are no more dies to attach.

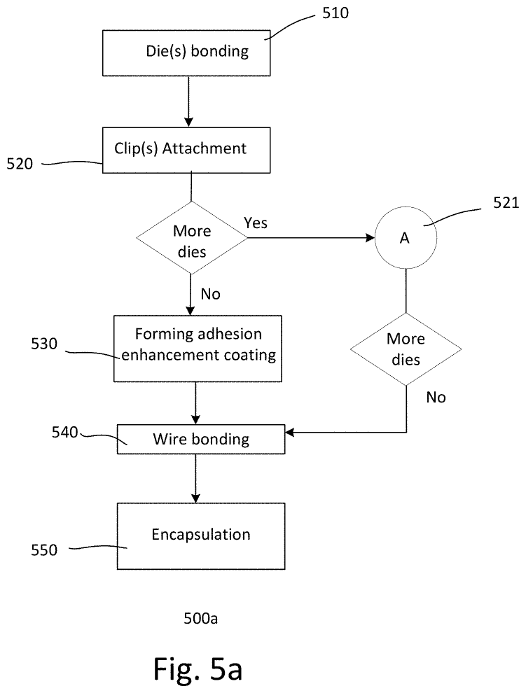

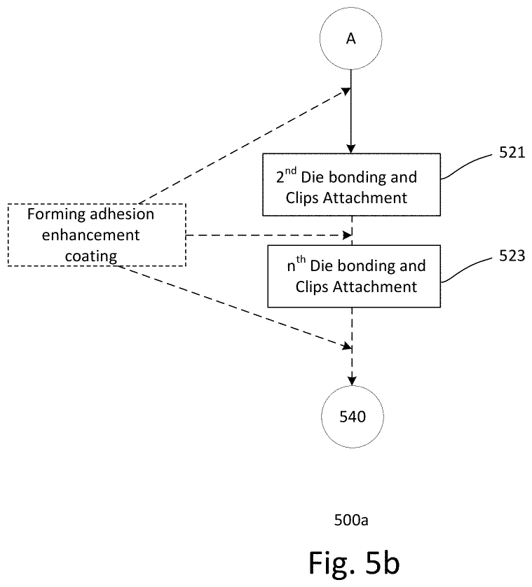

FIGS. 5a to 5b show another exemplary process flow of forming an embodiment of a semiconductor package. The package, for example, is similar to those described in FIGS. 1a to 1b, FIG. 2b, and FIGS. 4a to 4b. Common elements may not be described or described in detail.

Referring to FIGS. 5a to 5b, a process flow 500a is similar to that shown in FIGS. 4a and 4b, except the adhesion enhancement coating is not formed during the pre-assembly stage. As shown, the process flow is at the stage of assembling the package. Although the pre-assembly stage is not shown, it is to be understood that the process flow may include a typical pre-assembly stage where dies are formed on a wafer and diced to form individual dies, and clip bonds, if needed, are formed on a conductive strip and singulated to form individual clip bonds.

The assembly of the package begins in 510 when a die is attached to the die attach region of the package substrate. Clip bonds are attached thereafter in 520. If there are no more dies to attach, the process flow continues to 530. Alternatively, if there are more dies for bonding, the process flow proceeds to 521.

At 530, an adhesion enhancement coating is applied over the package substrate. The adhesion enhancement coating covers the exposed surfaces of the package substrate, the die, and the clip bonds. For example, a spraying mechanism is employed to dispose a solution of organosilanes over the package substrate. Other techniques, such as CVD or PVD, may also be useful for forming the adhesion enhancement coating. After which, wire bonds are formed in 540 before the package is encapsulated in 550.

If there are more dies to attach, a second set of die and clip bonds is sequentially attached in 521. For example, in the case of a multiple die stack configuration, a second die is stacked on top of a first clip bond and second clip bonds are attached to couple the second die to the terminal pads of the package substrate. Subsequent sets of die and clip bonds may be attached in 523. As shown, the adhesion enhancement coating may be formed between (n−1)th and nth attached sets of die and clip bonds. For example, between first and second attached sets of die and clip bonds. For example, the adhesion enhancement coating may be formed over the first attached set of die and clip bonds before the second set of die and clip bonds are attached. Preferably, the adhesion enhancement coating is formed over an attached set of die and clip bonds with the largest exposed surface area. Other configurations of providing the adhesion enhancement coating may also be useful. For example, the adhesion enhancement coating is formed over each attached set of die and clip bonds. For example, the number of adhesion enhancement coating layers corresponds to the number of die and clip bond sets. Alternatively, the adhesion enhancement coating may be formed after all the dies are attached and clip bonded. Once there are no more dies to attach, the process flow continues to form the wire bonds in 540 before encapsulating the package in 550.

Depending on the configuration of the semiconductor package, the process flow 500a may not include forming clip bonds or wire bonds. For example, in the case when the semiconductor package does not include clip bonds, no clip bonds are provided. For example, the adhesion enhancement coating is disposed over the package substrate to cover exposed surfaces of the package substrate and the die or dies. As for cases when the semiconductor package does not include wire bonds, the process flow moves on directly to form the encapsulation in 550 after there are no more dies to attach.

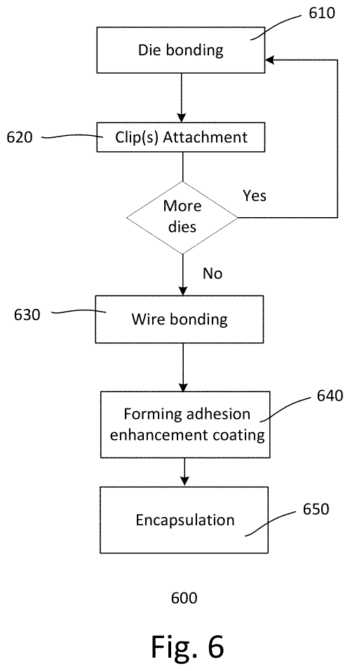

FIG. 6 illustrates a process flow 600 similar to the process flow 500a in FIGS. 5a to 5b, except that the adhesion enhancement coating is applied after wire bonding. Common elements may not be described or described in detail. As shown, after wire bonds are formed in 630, the adhesion enhancement coating is applied over the package substrate in 640 to cover the exposed surfaces of the package substrate, the dies, the clip bonds and the wire bonds. A spraying technique may be performed to dispose a solution of organosilanes over the package substrate. Alternatively, other techniques, such as CVD or PVD, may also be useful for forming the adhesion enhancement coating. The package is encapsulated in 650.

Depending on the configuration of the semiconductor package, the process flow 600 may not include forming clip bonds. For example, in the case when the semiconductor package does not include clip bonds, no clip bonds are provided in 620. For example, as shown, after attaching the die or dies to the die attach region in 610, the process continues to 630 without performing clip attachment. Wire bonds are formed in 630 before the adhesion enhancement coating is disposed over the package substrate in 640 to cover exposed surfaces of the package substrate, the die or dies, as well as the wire bonds.

The present disclosure may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

1. A device comprising:
a package substrate having top and bottom major package substrate surfaces, the top major package surface includes a die attach region;
a die disposed on the die attach region, wherein the die includes first and second major die surfaces, the second major die surface is attached to the die attach region;
an adhesion enhancement layer disposed on a metallic component of the device; and
an encapsulant, the encapsulant covers exposed portions of the package substrate and the die, wherein the adhesion enhancement layer enhances adhesion of the encapsulant to the metallic component of the device.

2. The device of claim 1 wherein the adhesion enhancement layer comprises a polysiloxane layer, the polysiloxane layer is configured to form covalent bonds with the encapsulant and the metallic component of the device.

3. The device of claim 2 wherein the polysiloxane layer is deposited on the metallic component of the device by spraying a solution comprising organosilanes on the metallic component of the device.

4. The device of claim 1 wherein the metallic component comprises a copper component.

5. The device of claim 1 wherein the package substrate comprises a leadframe, wherein the metallic component of the device comprises the leadframe.

6. The device of claim 5 wherein the leadframe is completely coated with the adhesion enhancement layer.

7. The device of claim 5 wherein exposed portions of the leadframe are coated with the adhesion enhancement layer.

8. The device of claim 5 comprises a clip bond coupled to the first die surface and a package pad of the package substrate, wherein the metallic component of the device comprises the clip bond and the leadframe.

9. The device of claim 8 wherein the leadframe and clip bond are completely coated with the adhesion enhancement layer.

10. The device of claim 8 wherein exposed portions of the leadframe and clip bond are coated with the adhesion enhancement layer.

11. The device of claim 8 wherein exposed portions of one of the leadframe and clip bond are coated with the adhesion enhancement layer and other of the leadframe and clip bond is completed coated with the adhesion enhancement layer.

12. The device of claim 2 comprises a clip bond coupled to the first die surface and a package pad of the package substrate, wherein the metallic component of the device comprises the clip bond.

13. The device of claim 12 wherein the clip bond is completely coated with the adhesion enhancement layer.

14. The device of claim 12 wherein exposed portions of the clip bond are coated with the adhesion enhancement layer.

15. A method for forming a device comprising:
providing a package substrate having top and bottom major package substrate surfaces, the top major package surface includes a die attach region;
attaching a second major die surface of a die onto the die attach region, wherein a first major die surface of the die includes a die pad; and
depositing an encapsulant on the package substrate to cover exposed portions of the package substrate and the die, the encapsulant bonds with an adhesion enhancement layer disposed on a metallic component of the device, wherein the adhesion enhancement layer enhances adhesion of the encapsulant to the metallic component of the device.

16. The method of claim 15 wherein the adhesion enhancement layer comprises a polysiloxane layer, the polysiloxane layer is configured to form covalent bonds with the encapsulant and the metallic component of the device.

17. The method of claim 16 further comprises
providing a clip bond singulated from a conductive sheet with a plurality of clip bonds, wherein the conductive sheet is coated with the polysiloxane layer;
attaching the clip bond to the die pad of the die and a package pad disposed on the top major package surface of the package substrate; and
wherein the encapsulant covers exposed portions of the package substrate, the die and the clip bond.

18. The method of claim 16 further comprises
attaching a clip bond to the die pad of the die and a package pad disposed on the top major package surface of the package substrate;
depositing the polysiloxane layer on the package substrate to coat exposed portions of the package substrate, the die and the clip bond; and
wherein the encapsulant covers exposed portions of the package substrate, the die and the clip bond.

19. The method of claim 16 wherein providing the package substrate comprises
depositing the polysiloxane layer on the package substrate to coat exposed portions of the package substrate.

20. The method of claim 19 further comprises
attaching a clip bond to the die pad of the die and a package pad disposed on the top major package surface of the package substrate; and
wherein the encapsulant covers exposed portions of the package substrate, the die and the clip bond.
